(19) United States
(12) Patent Application Publication
(10) Pub. No.: US 2007/0222074 A1
(43) Pub. Date: Sep. 27, 2007

(54) Electric Device With Vertical Component

(75) Inventors: Erik Petrus Antonius Maria Bakkers, Eindhoven (NL); Robertus Adrianus Maria Wolters, Eindhoven (NL); Johan Hendrik Klootwijk, Eindhoven (NL)

Correspondence Address: PHILIPS INTELLECTUAL PROPERTY & STANDARDS, P.O. BOX 3001, BRIARCLIFF MANOR, NY, 10510, US

(73) Assignee: KONINKLIJKE PHILIPS ELECTRONICS, N.V., EINDHOVEN (NL)

(21) Appl. No.: 11/569,175

(22) PCT Filed: May 19, 2005
(86) PCT No.: PCT/IB05/51634

§ 371 Date: Nov. 16, 2006

(30) Foreign Application Priority Data
May 26, 2004 (EP) 04102313.6

(51) Int. Cl. H01L 23/52; H01L 21/3205

(52) U.S. Cl. 257/750; 438/597; 257/E21.294; 257/E23.141

(57) ABSTRACT

A method of providing an electric device with a vertical component and the device itself are disclosed. The electric device may be a transistor device, such as a FET device, with a vertical channel, such as a gate around transistor, or double-gate transistor First an elongate structure, such as a nanowire is provided to a substrate. Subsequently, a first conductive layer separated from the substrate and from the elongate structure by a dielectric layer is provided. Further, a second conductive layer being separated from the first conductive layer by a separation layer is being provided in contact with at least a top section of the elongate structure.

The invention relates to a method of fabricating an electric device with a vertical component and to a device with a vertical component. The invention relates particularly to a FET device with a vertical channel.

As the integrated circuit (IC) technology has developed, the performance of integrated circuits has continuously increased at a remarkable pace. The continuous advancement is due to the ability of continually shrinking line widths so that more and more transistors fit into the same area and thereby enabling more and more functions per unit area.

Shrinking the conventional MOSFET beyond the 50 nm technology node, however, requires innovations to circumvent barriers due to the fundamental physics that constrains the conventional MOSFET. Two of the often-cited problems are tunneling of charge carriers through the thin gate dielectric and control of the charge density in the active channel. An improvement of the current planar MOSFET structures is the implementation of a double-gate FET. In the double gate geometry the gate capacitance has increased, giving better electrostatic control of the channel.

In the PCT patent application WO 98/42026 a method of manufacturing a vertical MOS transistor is disclosed. In the method the gate length is determined by etching a conductive layer until an appropriate thickness. This requires a very good control of the etching time which is difficult, in particular when the transistor has relatively small dimensions.

The present invention seeks to provide an improved method of fabricating an electric device. Accordingly there is provided, in a first aspect, a method comprising the steps of:

a) providing a substrate having a main surface with an elongate structure protruding from the main surface, and

b) providing the main surface and the elongate structure with a dielectric layer,

c) providing a set of layers comprising a first conductive layer, the first conductive layer being electrically insulated from the substrate and from the elongate structure by the dielectric layer, the layers of the set each having a respective thickness perpendicular to the main surface, the first conductive layer having a part facing the elongate structure over a length, the length being determined by the respective thickness of the layers of the set.

Thus, the present invention provides a method where the size, such as the length and/or the thickness, of the part of the first conductive layer facing the elongate structure is determined by the respective thickness of the layers of the set. It is an advantage to use the thickness of a layer to determine the size of an element, since the thickness of one or more layers may be very precisely controlled. The thickness of a layer may be controlled down to one or a few atomic layers, or mono-layers. The definition of a mono-layer is known in the art. The thickness of a layer may thus be controlled with nanoscopic resolution, microscopic resolution, or mesoscopic resolution.

The electric device may be an electronic device, such as a semiconductor based electronic device. For example, the electronic device may be a transistor device, such as a gate-around transistor, or double gate transistor.

The substrate and/or the elongate structure may be of an insulating material, i.e. a material with such low conductivity that the flow of current through it may be neglected, they may be of a conducting material, i.e. a material with a conductivity of that of a metal, or they may be of a semiconductor material, i.e. a material with a conductivity between that of a metal and an insulator, and where the conductivity may depend on various properties such as the impurity level. The substrate and elongate structure need not be of the same conductivity, i.e. one may be an insulator while the other may be a semiconductor, but both may also be of the same conductivity, such as both materials may be semiconductor materials.

The material of the substrate and/or the elongate structure may each include more than one element from the periodic table, i.e. the material of the substrate and/or the elongate structure may each be a binary, a ternary, or a quaternary compounds, or may each be a compound containing more than five elements. The substrate need not be a substrate of a bulk material. The substrate may be a top layer supported on a bulk material of the same or a different material. The substrate may even be a stack of layers supported by a bulk material. As an example, the substrate may be a top layer of SiGe supported by a Si substrate, e.g. a Si wafer.

The elongate structure may be a nanostructure, mesostructure or microstructure, such as a nanostructure grown on the substrate, e.g. by means of the vapor-liquid-solid growth method (VLS growth). It may be an advantage to provide a nanostructure as the elongate structure since problems with e.g. lattice mismatch between a lattice of the elongate structure and a lattice of the substrate may be avoided and an epitaxial relationship between the substrate and the elongate structure may be provided.

The elongate structure may project away from the substrate. The elongate structure may be provided so that it is protruding substantially perpendicular to the substrate, however the elongate structure may also be provided so that it is protruding from the substrate with an angle different from 90 degrees. The angle may depend upon the nature of the elongate structure and the substrate, for example nanowires of InP grown on Ge(111) may grow in two orientations: a part protruding perpendicularly from the substrate and a part with an angle of 35 degrees from the substrate. However any angle may be envisioned, and for an ensemble of elongate structures on a substrate, a variety of angles may be present or even a distribution of angles may be present. The elongate structure may possess a specific aspect ratio, i.e. a specific length-to-diameter ratio. The aspect ratio may be larger than 10, such as larger than 25, such as larger than 50, such as larger than 100, such as larger than 250. The diameter may be obtained perpendicularly to the longitudinal direction of the elongate structure.

The elongate structure may be a substantially single-crystal structure. It may be advantageous to provide a single-crystal structure, e.g. in relation with theoretical elaboration of current transport through the structure, or other types of theoretical support or insight into properties of the structure. Further, other advantages of substantially single-crystal structures include that a device with a more well-defined operation may be achieved, e.g. a transistor device with a better defined voltage threshold, with less leak current, with better conductivity, etc. may be obtained, than for devices based on non-single crystal structures.

The elongate structure may be intrinsic semiconducting, doped to be p-type semiconducting or doped to be n-type semiconducting. Further, the elongate structure may comprise at least two segments, and where each segment is either an intrinsic semiconductor, or an n-type semiconductor or a p-type semiconductor. Different types of semiconductor device components may therefore be provided, such as components comprising a pn-junction, a pnp-junction, a npn-junction, etc. Segments in the longitudinal direction may e.g. be obtained using a vapor deposition method, and during growth change the composition of the vapor.

The elongate structure may be the functional component of a device selected from the group consisting of phonon bandgap devices, quantum dot devices, thermoelectric devices, photonic devices, nanoelectromechanical actuators, nanoelectromechanical sensors, field-effect transistors, infrared detectors, resonant tunneling diodes, single electron transistors, infrared detectors, magnetic sensors, light emitting devices, optical modulators, optical detectors, optical waveguides, optical couplers, optical switches, and lasers.

A dielectric layer is provided to the main surface of the substrate and to the elongate structure. The dielectric layer may be provided in one or more steps. The dielectric layer may be constituted of one or more materials. The thickness of the dielectric layer may vary across the combined structure of the substrate and the elongate structure.

The dielectric layer may comprise a first and a second dielectric layer. The first dielectric layer may cover the main surface of the substrate and adjoin and be in contact with at least a section of the elongate structure. The elongate structure may act as a current carrying channel, e.g. the current channel in a transistor device, such as a FET device. The first dielectric layer may be, or may provide, a dielectric barrier separating the substrate from one or more gate electrodes. The first dielectric layer may be of any suitable material, such as SiO₂ or Spin-on-glass (SOG). The first dielectric layer may be provided as a layer with a certain thickness, such as in the range 10-1000 nm, such as in the range 50-500 nm, such as in the range 100-250 nm. The first dielectric layer may be provided with a dielectric coupling so as to obtain a low, a negligible or no parasitic capacitance between the substrate and a gate electrode. The first dielectric layer may be provided with a dielectric constant lower than the dielectric constant of SiO₂, the first dielectric layer may be a low-K material, such materials are known in the art. Examples of low-K materials which may be used are such materials as: SILK (trademark of Dow Chemical), Black diamond (trademark of Applied Materials) and Aurora (trademark of ASMI).

The second dielectric layer may cover at least part of the elongate structure. However, the second dielectric layer may be provided to the entire sample. The second dielectric layer may be provided subsequently to providing the first dielectric layer. The second dielectric layer may be provided by using a chemical vapor deposition (CVD) technique, such as plasma enhanced CVD (PECVD). The second dielectric layer may also be provided by atomic layer deposition (ALD). The second dielectric layer may be, or may provide, a dielectric barrier separating the elongate structure from one or more gate electrodes. Thus, the second dielectric layer may be, or may provide, a gate dielectric. The second dielectric layer may be of any suitable material, such as SiO₂. The second dielectric layer may be provided with a certain thickness, such as in the range 1-100 nm, such as in the range 1.5-50 nm, such as in the range 2-10 nm, such as 5 nm. The thickness of the second dielectric layer may be chosen so as to obtain a sufficient electrical insulation between a conductive material and the elongate structure. Especially the lower limit of the thickness of the second dielectric layer may depend upon that a sufficient electrical insulation is obtained. The second dielectric layer may be provided with a dielectric constant higher than the dielectric constant of SiO₂, the second dielectric layer may be of a high-K material, such materials are known in the art. Examples of High-K materials which may be used are such materials as tantalum oxide or hafnium oxide. The upper limit of the thickness of the dielectric layer may be determined by a desired change in the channel conductance for a given potential difference between the first conductive layer and the channel, i.e. the elongate structure. The dielectric layer between the gate and the channel is between 1-10 nm in industrial important systems.

Above, various aspects of the dielectric layer are discussed in connection with a first and a second dielectric layer, but it is to be understood that alternatively a single dielectric layer may be provided, or more than two layers may be provided. The first and second dielectric layers as described above may also constitute a first and a second part of the dielectric layer.

The set of layers comprising at least a first conductive layer, the first conductive layer may be provided onto at least part of the sample. The first conductive layer may be a layer of Al, Pt, Zr, Hf, TiW, Cr, Ta or Zn, ITO or any other suitable material. The first conductive layer may act as an electrode, such as a gate electrode in a FET device.

The first conductive layer may be provided to the substrate by using a sputter technique or any other relevant technique, so that a substantial uniform and continuous layer of the first conductive layer may be deposited.

Prior to providing the set of layers, the top end, or outer end, of the elongate structure may be encapsulated by a cap, such as a bell-shaped cap. The encapsulation of the top end may be provided in a dedicated process step, however it may also be provided during the deposition process of the dielectric layer, e.g. in connection with deposition of a second dielectric layer as described above, since in such a process more material may be deposited at edges. More material may be deposited at edges due to material transport properties. This effect is known in the art as shadowing effect (see e.g. Silicon Processing in the VLSI era, S. Wolf and R. N. Tauber, 6th ed., 1986, p. 186, Attice Press, Sunset Beach, Calif.).

The first conductive layer may be provided to the substrate by using a thermal deposition technique. In an embodiment where the elongate structure is encapsulated by a cap, shadowing from the cap may result in that a first part of the conductive layer may be deposited on the dielectric layer as a layer substantially co-planar with the substrate, and a second part of the conductive layer may be deposited on the top of the cap.

The thickness of the first conductive layer may depend upon the deposition method used, the first conductive layer may have a thickness between 10 nm and 1 micrometer, such as between 25 and 500 nm, such as between 50 and 250 nm, such as between 75 and 100 nm.

The step of providing the set of layers may comprise the sub-steps of:

c1) providing the first conductive layer,

c2) providing a protection layer covering a part of the first conductive layer facing the elongate structure, a remainder of the first conductive layer facing the elongate structure being exposed,

c3) removing the remainder of the first conductive layer using the protection layer as a mask.

The protection layer may thus be a layer comprised in the set of layers. The protection layer may have a certain thickness so that the covered part of the first conductive layer comprises a first part and a second part. The first part being the part of the first conductive layer being separated form the substrate by at least the dielectric layer, and the second part being a part of the first conduct layer being separated from the elongate structure at least by the dielectric layer. The thickness of the protection layer may be of a similar thickness as the first dielectric layer as described above. The protection layer may be a SOG layer or may be a photoresist layer, such as PMMA, PIQ or BCB, spincasted on the first conductive layer.

An etch treatment may be provided which removes the first conductive layer more effectively than the protection layer resulting in that the part of the first conductive layer covered by the protection layer remain whereas the part not covered by the protection layer is removed. The protection layer may subsequently be removed after etching, e.g. by dissolving it in boiling acetone.

According to the invention the gate length is determined in a reliable way because it depends on the thickness of the conductive layer and on the thickness of the protection layer which may be spun onto the conductive layer. A better determination of the gate length may in this way be obtained than for methods where the gate length is determined by etching until a desired length is obtained. Such methods requires very good control of the etching time which is difficult, in particular when the transistor has relatively small dimensions such as e.g. a channel length of 200 nm or below.

A second conductive layer may be provided in electric contact with at least a top end of the elongate structure. The second conductive layer may act as a top contact. The top contact may act as the source or drain of a transistor.

A separation layer may be provided for electrically insulating the second conductive layer form the first conductive layer. The separation layer may be of SiO₂.

Prior to providing the second conductive layer, a top part of the separation layer may be removed to expose a part of the elongate structure. The top part of the separation layer may be removed by polishing. The sample may be polished until the elongate structure reaches the resulting top surface, or the sample may be polished until a desired thickness is obtained.

In order to increase the contact area of the elongate structure and the second conductive layer a selectively etching of the a top part of the separation layer may be conducted. A top section of the elongate structure may thus be incorporated into the second conductive layer, thereby facilitating an improved electric contact between the elongate structure and the second conductive layer.

The second conductive layers may be of any suitable materials, e.g. a metal or a mixture of metals, such as Ti/Al/Au or Ti/Zn/Au, a conductive polymer or another type of conducting materials, such as indium tin oxide (ITO). The second conductive layer may be provided with a certain thickness, such as in the range 10-1000 nm, such as in the range 50-500 nm, such as in the range 100-250 nm. The substrate and the second conductive layer may be electrically connected by the elongate structure, and depending upon the conductivity of the elongate structure, a conducting or a semiconducting connection may be obtained.

Photoresist may be spincasted onto the polished surface. By means of optical lithography contact areas may be defined in the photoresist, and the second conductive layer may be provided in accordance with the lithographically defined areas. The second conductive layer may be provided in the form of contact pads.

According to a second aspect of the invention, an electric device is provided, the device comprising:

a substrate having a main surface with a protruding elongate structure in electrical contact with the substrate, and

a first conductive layer being electrically insulated from the substrate and from the elongate structure by a dielectric layer, the first conductive layer having a part facing the elongate structure over a length, the part of the first conductive layer facing the elongate structure having a thickness perpendicular to the main surface which is either larger or smaller than a thickness of a remaining portion of the first conductive layer.

Such a device is an improvement over e.g. the current planar MOSFET devices. The gate-around geometry facilitates enhanced gate capacitance and better control of the charge carriers in the channel, as well as freedom of material for the channel.

These and other aspects, features and/or advantages of the invention will be apparent from and elucidated with reference to the embodiments described hereinafter.

Embodiments of the invention will be described, by way of example only, with reference to the drawings, in which

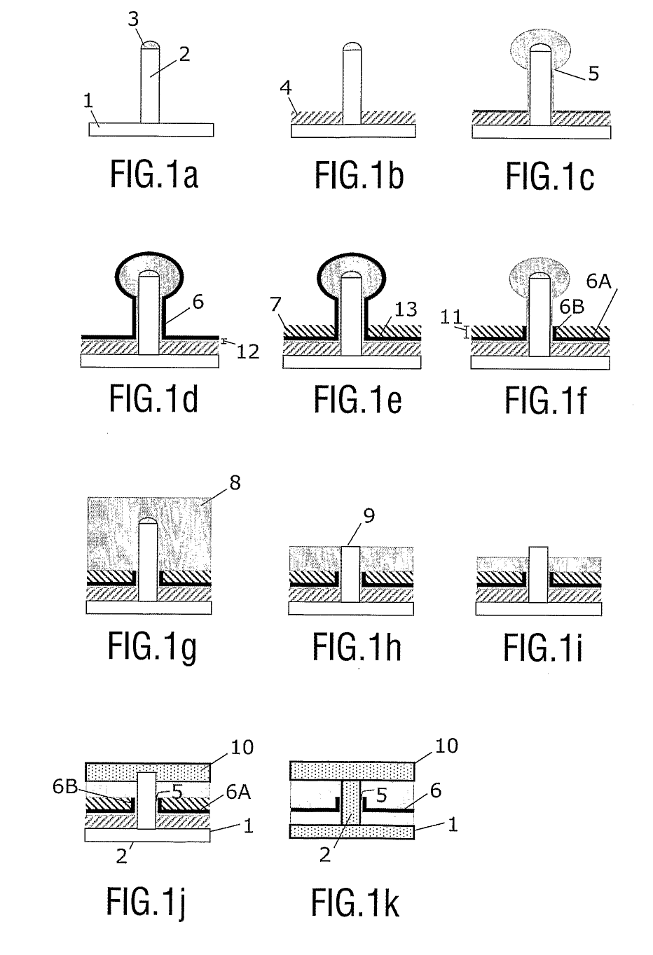

FIG. 1 is a schematic illustration of process steps involved in providing a first embodiment of a gate-around-transistor,

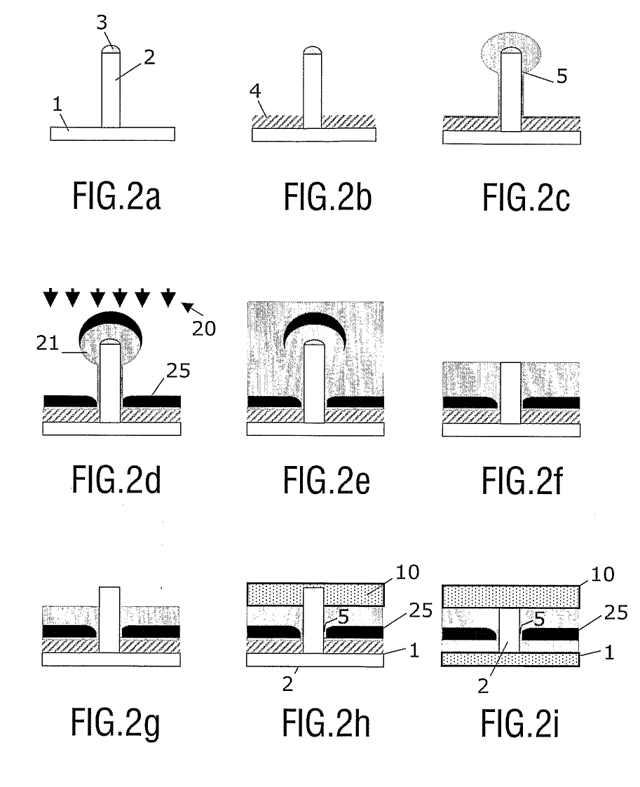

FIG. 2 is a schematic illustration of process steps involved in providing a second embodiment of a gate-around-transistor, and

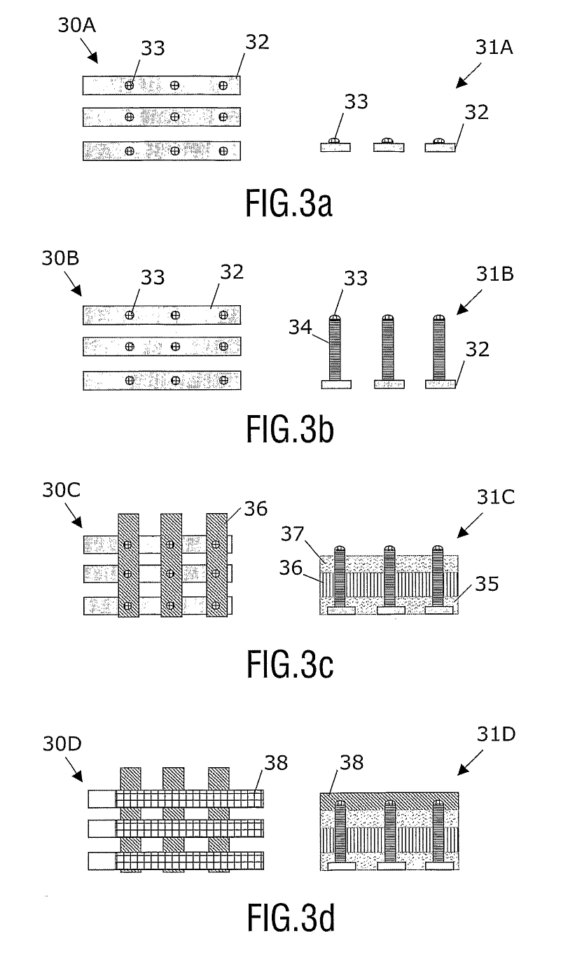

FIG. 3 is a schematic illustration of process steps involved in providing an array of gate-around-transistors.

The figures are schematic and not drawn to scale. Like reference numerals in different figures refer to the same or similar parts. The figures and the description are merely examples and should not be considered to set the scope of the present invention.

In this section embodiments are described where the elongate structures is a nanostructure and more specifically a nanowire. The term nanowire is used in connection with the description of specific embodiments and should be taken as an example of an elongate structure, not as a limitation of the term elongate structure.

The nanowires described in the embodiments may be grown by using the VLS-growth method. It is, however, important to notice that the process steps in connection with the presented embodiments may provide a gate-around-transistor irrespectively of how the nanowires are provided. The sole requirement for the process steps to provide a gate-around-transistor, is to provide, as a starting point, a substantially protruding structure from the substrate.

The nanowires may e.g. be homoepitaxially grown, such as Si nanowires on a Si substrate, the nanowires may also e.g. be heteroepitially grown, such as InP nanowires on a Ge substrate.

In FIGS. 1 and 2 two embodiments of the process steps involved in the fabrication of a gate-around-transistor are shown. Firstly the embodiment illustrated in FIG. 1 is described, and subsequently the embodiment illustrated in FIG. 2.

In FIG. 1(a) a nanowire 2 is provided substantially vertically on a semiconductor substrate 1. In case the nanowire is grown using the VLS growth method, the nanowire is terminated at its free end by a metal particle 3.

In the subsequent process step as illustrated in FIG. 1(b), a first dielectric layer 4 is provided onto the substrate. The layer covers all parts of the substrate not in contact with a nanowire. The layer adjoins at least a section of the nanowire. The first dielectric layer may e.g. be a Spin-on-glass (SOG). The thickness of the layer may be in the order of 100 nm. As will become evident below, the SOG is applied to electrically insulate the substrate 1 from the gate electrode 6A. The SOG is after deposition thermally annealed at 300° C. The SOG may e.g. be of the type provided by Tokyo ohka or Allied Signal.

In the subsequent step illustrated in FIG. 1(c) a second dielectric layer 5 is provided. The layer may have a thickness 12 in the order of 10-50 nm. The layer may e.g. be a SiO₂ layer deposited by plasma enhanced chemical vapor deposition (PECVD) or by atomic layer deposition (ALD). The layer is deposited while the sample temperature is maintained at T=300° C. In this way the complete nanowire is covered by a thin layer, however at edges more material will be deposited due to material transport properties.

In the subsequent step illustrated in FIG. 1(d) a first conducting layer 6 is provided in the form of a thin (50 nm) metal layer. Such as an Al layer deposited by means of sputtering.

In the next process step (FIG. 1(e)) a protection layer 7 is provided. The protection layer has a similar thickness as the first dielectric layer. The protection layer may be a second SOG layer spincasted on the metal layer.

The dielectric-metal interface 13 can be modified by a primer, for instance HMDS, to adjust the contact angle between the surface and the next layer. Alternatively, a thin (such as 50 nm) SiO₂ layer can be deposited directly on the metal by PECVD.

The part of the first conducting layer which is protruding above the protection layer 7, is etched in a subsequent step as illustrated in FIG. 5(f). The thickness 11 of the protection layer is larger than the thickness 12 of the first conductive layer. The difference in thickness may be a factor 10 or more. This thickness difference result in, after the etch process of the part of the first conducting layer which is protruding above the protection layer, that the first conductive layer obtains an L-shape 6A, 6B. The etching may for an Al layer be performed using PES. Other materials may be etched by using the appropriate etch method. For example, TiW may be etched using an H₂O₂/NH₄OH mixture, Pt may be etched using an HCl/HNO₃ mixture, Zn may by etched using HCl, Co and Ni may be etched using an H₂O₂/H₂SO₄ mixture and Ta, Zr and Hf may be etched using HF.

The protection layer spincasted on the surface of the conducting layer before the etch process may act as a vertical mask during the metal etch process. It is expected that the protection layer will only cover the horizontal part of the metal film. The protection layer may be a resist layer which is not structured by lithography, but by the surface structure itself, it may thus be a self-assembling resist layer. After etching the protection layer may be removed by dissolving it in boiling acetone.

The complete sample is subsequently, as illustrated in FIG. 1(g), covered by a separation layer 8 (˜2 microns thick). The layer may e.g. be a SiO₂ layer deposited by PECVD at T=300° C.

The sample is then polished until the top surface 9 of the nanowire is reached, or until a desired thickness is obtained (FIG. 1(h)) and the top of the separation layer is removed such that a part of a nanowire is freed from the separation layer (FIG. 1(i)). The top of the polished surface may be removed to enlarge the contact area of the nanowire. The removal of the top of the polished layer may e.g. be obtained by etching. A SiO₂ layer may be etched in a buffered oxide etch such as NH₄F or HF.

In FIG. 1(j) a second conductive layer 10 is provided as a top layer, i.e. a top contact metal is deposited on the nanowire. The second conductive layer may be patterned in accordance with a desired pattern, e.g. a grid and metal pads may be provided. As examples of top contact metal pads, a Ti/Al/Au layer may be deposited for n-type InP nanowires, and a Ti/Zn/Au layer for p-type InP nanowires. Also a transparent electrode my be provided, such as an ITO electrode for opto-electronic applications, e.g. a LED on a Si-chip.

In order to establish a current conducting contact to the gate electrode, the SiO₂ of the separation layer is etched in an F₂ plasma in an area where no top contact pads is defined. The etching is stopped at the gate metal. The nanowires protruding the metal layer are removed. For InP nanowires, a selective InP etch may be used (for instance HCl).

Thus, the electronic device as illustrated in FIG. 1(k) is a gate-around-transistor. The gate-around-transistor comprises a drain 1, a current channel 2, a source 10, a gate electrode 6 with a part encircling the nanowire, and a gate dielectric 5 separating the nanowire from the electrode.

In FIG. 2(a) to (h) an alternative embodiment and an alternative process diagram is presented. FIGS. 2(a) to (c) are similar to the process steps described in connection with FIGS. 1(a)-(c).

In the process step described in FIG. 2(d) the electrode 25 is deposited by means of thermal vapor deposition 20. A thin aluminum layer (50 nm) may e.g. be deposited. In the vapor deposition process, the bell-shaped cap 21 of SiO₂-deposit at the top of the nanowire acts as a shadow mask.

The subsequent steps (e) to (h) are similar to the steps described in connection with FIG. 1(g) to FIG. 1(j).

Thus, the main structural difference between the gate-around-transistor resulting from the process described in connection with FIG. 1, and the gate-around-transistor resulting from the process described in connection with FIG. 2, is the geometrical aspects of the gate electrode.

The electronic device as illustrated in FIG. 2(i) is thus also a gate-around-transistor. The gate-around-transistor comprises a drain 1, a current channel 2, a source 10, a gate electrode 25, and a gate dielectric 5 separating the nanotube from the electrode.

Fabricating a gate-around structure based on a vertical nanowire offers a number of advantages. An enhanced gate capacitance with respect to the gate-around geometry may be obtained. Furthermore, the nanowire element may be chosen based on the requirement of a given component. For example, if a better control of the charge density in the channel is desirable, a high-mobility material, such as InGaAs, may be grown as the channel.

In FIGS. 1 and 2 the fabrication of a single gate-around-transistor has been described. By combining the process steps with those described in connection with FIG. 3, an array of gate-around-transistors may be provided. Other schemes for providing an array of nanostructures may, however, also be envisioned.

In FIG. 3 four process steps ((a) to (d)) involved in providing an array of gate-around-transistors are schematically illustrated. The figures on the left side (30A, 30B, 30C and 30D) provide a top-view, whereas the figures on the right side (31A, 31B, 31C and 31D) illustrate the corresponding side-view of the process steps.

In the first process step (FIG. 3(a)) rows 32 of the substrate material are firstly provided. The rows may be provided using a lithography process. Metal particles 33, such as gold particles, may be provided in arrays along the substrate rows at positions where the nanowires should be grown.

In the process step illustrated in FIG. 3(b) nanowires of e.g. InP or another semiconductor material are grown using the VLS growth method. Nanowires 34 protruding from the substrate at the position of the metal particles are thereby provided.

In the process step in FIG. 3(c) a dielectric material 35 is provided. On top of the dielectric layer is a first conducting material provided in rows 36. The rows may be provided using a suitable lithographic method. A separation layer 37 is also provided on top of the first conducting material.

In the process step in FIG. 3(d) rows 38 of a second conductive material are provided. The second conductive material may act as a top contact.

Thus, by following the process steps illustrated in FIG. 3 electrical connection may be made to individual nanowires by controlling which set of rows 32, 36, 38 that is addressed. In this embodiment, only a single nanowire is present in the area covering the intersections of the rows. However, more than one nanowires, such as a bundle of nanowires may also be present in the areas covering the individual intersections.

Although the present invention has been described in connection with preferred embodiments, it is not intended to be limited to the specific form set forth herein. Rather, the scope of the present invention is limited only by the accompanying claims.

In this section, certain specific details of the disclosed embodiment such as material choices, preparation conditions, techniques, etc., are set forth for purposes of explanation rather than limitation, so as to provide a clear and thorough understanding of the present invention. However, it should be understood readily by those skilled in this art, that the present invention may be practiced in other embodiments which do not conform exactly to the details set forth herein, without departing significantly from the spirit and scope of this disclosure. Further, in this context, and for the purposes of brevity and clarity, detailed descriptions of well-known apparatus, circuits and methodology have been omitted so as to avoid unnecessary detail and possible confusion.

It will be appreciated that reference to the singular is also intended to encompass the plural and vice versa, and references to a specific numbers of features or devices are not to be construed as limiting the invention to that specific number of features or devices. Moreover, expressions such as “include”, “comprise”, “has”, “have”, “incorporate”, “contain” and “encompass” are to be construed to be non-exclusive, namely such expressions are to be construed not to exclude other items being present.

Reference signs are included in the claims, however the inclusion of the reference signs is only for clarity reasons and should not be construed as limiting the scope of the claims.

1. Method of fabricating an electric device, the method comprising the steps of:
a) providing a substrate (1, 32) having a main surface with an elongate structure (2, 34) protruding from the main surface,
b) providing the main surface and the elongate structure with a dielectric layer (4, 5, 35), and
c) providing a set of layers (6, 7, 25, 36) comprising a first conductive layer (6, 25, 36), the first conductive layer being electrically insulated from the substrate and from the elongate structure by the dielectric layer (5), the layers of the set each having a respective thickness (11, 12) perpendicular to the main surface, the first conductive layer having a part (6B) facing the elongate structure over a length, the length being determined by the respective thickness of the layers of the set.

2. Method as claimed in claim 1, wherein the step of providing the set of layers comprises the sub-steps of:
c1) providing the first conductive layer (6),
c2) providing a protection layer (7) covering a part of the first conductive layer facing the elongate structure, a remainder of the first conductive layer facing the elongate structure being exposed, and
c3) removing the remainder of the first conductive layer using the protection layer as a mask.

3. Method as claimed in claim 2, wherein the material removal treatment comprises an etch treatment which removes the first conductive layer (6) more effectively than the protection layer (7).

4. Method as claimed in claim 2, wherein the protection layer (7) is provided by spin coating.

5. Method as claimed in claim 1, wherein prior to providing the set of layers an outer end of the elongated structure is encapsulated with a cap (21).

6. Method as claimed in claim 5, wherein the set of layers consists of the first conductive layer (25).

7. Method as claimed in claim 1, further comprising the step of:
d) providing a second conductive layer (10, 37), the second conductive layer being in contact with at least a top section of the elongate structure.

8. Method as claimed in claim 7, wherein between steps c) and d) a separation layer (8) is provided for electrically insulating the second conductive layer (10, 37) from the first conductive layer (6, 25, 35).

9. Method as claimed in claim 8, wherein prior to providing the second conductive layer a top part of the separation layer is removed to expose a part (9) of the elongate structure.

10. An electric device comprising:
a substrate (1) having a main surface with a protruding elongate structure (2) in electrical contact with the substrate, and
a first conductive layer (6) being electrically insulated from the substrate and from the elongate structure by a dielectric layer (4, 5), the first conductive layer (6) having a part facing the elongate structure over a length, the part of the first conductive layer facing the elongate structure having a thickness perpendicular to the main surface which is larger than a thickness of a remaining portion of the first conductive layer.

11. An electric device comprising:
a substrate (1) having a main surface with a protruding elongate structure (2) in electrical contact with the substrate, and
a first conductive layer (25) being electrically insulated from the substrate and from the elongate structure by a dielectric layer (4, 5), the first conductive layer having a part facing the elongate structure over a length, the part of the first conductive layer facing the elongate structure having a thickness perpendicular to the main surface which is smaller than a thickness of a remaining portion of the first conductive layer.
